(19) United States
(12) Patent Application Publication
(10) Pub. No.: US 2018/0282653 A1
(43) Pub. Date: Oct. 4, 2018

(54) METHOD OF LUBRICATING AN INTERNAL COMBUSTION ENGINE

(71) Applicant: The Lubrizol Corporation, Wickliffe, OH (US)

(72) Inventor: Matthew D. Gieselman, Wickliffe, OH (US)

(21) Appl. No.: 16/001,315

(22) Filed: Jun. 6, 2018

Related U.S. Application Data
(63) Continuation of application No. 15/124,765, filed on Sep. 9, 2016, now abandoned.
(60) Provisional application No. 61/951,127, filed on Mar. 11, 2014.

(51) Int. Cl. C10M 139/00; C10M 133/56; C10M 141/12; C10M 133/58; C10M 169/04

(52) U.S. Cl. CPC C10M 139/00; H05K 999/99; C10N 2230/18; C10M 133/56; C10M 141/12; C10M 2203/1025; C10M 2205/022; C10N 2030/04; C10M 133/58; C10M 169/04; C10M 2215/30; C10M 2227/00; C10M 2207/026

(57) ABSTRACT

The invention relates to a method of lubricating an internal combustion engine comprising supplying to the engine a lubricating composition comprising: an oil of lubricating viscosity, 2.3 wt % to 4 wt % of a dispersant package, wherein the dispersant package comprises: a borated succinimide dispersant obtainable by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and a non-borated succinimide dispersant obtained by a “Diels-Alder” reaction. The ratio of non-borated succinimide dispersant to borated succinimide dispersant is 90:10 to 20:80, and the borated succinimide has 0.2 wt % to 1.3 wt % boron on an oil-free basis of the dispersant.

### CROSS REFERENCE TO RELATED APPLICATIONS

This application is a continuation of application Ser. No. 15/124,765 filed on Sep. 9, 2016 which is a 371 of International Application Serial No. PCT/US2015/015990 filed Feb. 16, 2015 which claims the benefit of U.S. Provisional Application Ser. No. 61/951,127 filed on Mar. 11, 2014.

### FIELD OF INVENTION

The invention relates to a method of lubricating an internal combustion engine comprising supplying to the engine a lubricating composition comprising:an oil of lubricating viscosity, 2.3 wt % to 4 wt % of a dispersant package, wherein the dispersant package comprises: a borated succinimide dispersant, wherein the borated succinimide dispersant is obtained/obtainable by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and a non-borated succinimide dispersant, wherein the non-borated succinimide dispersant is obtained/obtainable by a “Diels-Alder” reaction of a polyalkylene with an acylating agent to form an intermediate, and reacting the intermediate with an aminoalcohol or amine to form a non-borated succinimide dispersant, wherein the ratio of non-borated succinimide dispersant to borated succinimide dispersant is 90:10 to 20:80, and the borated succinimide has 0.2 wt % to 1.3 wt % boron on an oil-free basis of the dispersant.

### BACKGROUND OF THE INVENTION

Polyolefin succinimide dispersants are known in lubricants. Among these are polyisobutylene succinimide that can be borated, or treated with other salting agents, as well as un-derivatised polyisobutylene succinimide. Polyolefin succinimide dispersants are believed to be useful for assisting in maintaining engine cleanliness (for example Sequence IIIG test), or control of sludge (for example Sequence VG test) and/or soot, modifying friction properties of a lubricant (possibly to modify fuel economy, for example in Sequence VID test).

### SUMMARY OF THE INVENTION

The present invention allows for an internal combustion engine (typically a compression ignited engine) to have at least one of improved fuel economy, reduced friction, improved soot dispersion, reduced deposit formation, reduced wear and improved cleanliness.

As used herein reference to the amounts of additives present in the lubricating composition disclosed herein are quoted on an oil free basis, i.e., amount of actives, unless otherwise indicated.

As used herein, the transitional term “comprising,” which is synonymous with “including,” “containing,” or “characterized by,” is inclusive or open-ended and does not exclude additional, un-recited elements or method steps. However, in each recitation of “comprising” herein, it is intended that the term also encompass, as alternative embodiments, the phrases “consisting essentially of” and “consisting of,” where “consisting of” excludes any element or step not specified and “consisting essentially of” permits the inclusion of additional un-recited elements or steps that do not materially affect the basic, essential and novel characteristics of the composition or method under consideration.

In one embodiment the invention relates to a method of lubricating an internal combustion engine comprising supplying to the engine a lubricating composition comprising:

an oil of lubricating viscosity,

2.3 wt % to 4 wt % of a dispersant package, wherein the dispersant package comprises:

a borated succinimide dispersant, wherein the borated succinimide dispersant may be obtained/obtainable by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and

a non-borated succinimide dispersant, wherein the non-borated succinimide dispersant may be obtained/obtainable by a “Diels-Alder” reaction of a polyalkylene with an acylating agent to form an intermediate, and reacting the intermediate with an aminoalcohol or amine to form a non-borated succinimide dispersant,

wherein
the ratio of non-borated succinimide dispersant to borated succinimide dispersant may be 90:10 to 20:80, and
the borated succinimide has 0.2 wt % to 1.3 wt % boron on an oil-free basis of the dispersant.

In one embodiment the invention relates to a method of lubricating an internal combustion engine comprising supplying to the engine a lubricating composition comprising:

an oil of lubricating viscosity,

2.3 wt % to 4 wt % of a dispersant package, wherein the dispersant package comprises:

a borated succinimide dispersant, wherein the borated succinimide dispersant may be obtained/obtainable by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and

a non-borated succinimide dispersant, wherein the non-borated succinimide dispersant may be obtained/obtainable by a “Diels-Alder” reaction of a polyalkylene with an acylating agent to form an intermediate, and reacting the intermediate with an aminoalcohol or amine to form a non-borated succinimide dispersant,

wherein
the ratio of non-borated succinimide dispersant to borated succinimide dispersant may be 90:10 to 20:80, and
the borated succinimide has 0.4 wt % to 0.6 wt % boron on an oil-free basis of the dispersant.

In one embodiment the invention relates to a method of lubricating an internal combustion engine comprising supplying to the engine a lubricating composition comprising:

an oil of lubricating viscosity,

2.3 wt % to 4 wt % of a dispersant package, wherein the dispersant package comprises:

a borated succinimide dispersant, wherein the borated succinimide dispersant comprises a non-cyclic linkage between a polyalkylene and an acylating agent,

a non-borated succinimide dispersant, wherein the non-borated succinimide dispersant comprises a carbocyclic linkage between a polyalkylene and an acylating agent,

wherein
the ratio of non-borated succinimide dispersant to borated succinimide dispersant may be 90:10 to 20:80, and
the borated succinimide has 0.2 wt % to 1.3 wt % boron on an oil-free basis of the dispersant.

In one embodiment the invention relates to a lubricating composition comprising:

an oil of lubricating viscosity,

2.3 wt % to 4 wt % of a dispersant package, wherein the dispersant package comprises:

a borated succinimide dispersant, wherein the borated succinimide dispersant comprises a non-cyclic linkage between a polyalkylene and an acylating agent,

a non-borated succinimide dispersant, wherein the non-borated succinimide dispersant comprises a carbocyclic linkage between a polyalkylene and an acylating agent,

wherein
the ratio of non-borated succinimide dispersant to borated succinimide dispersant may be 90:10 to 20:80,
the borated succinimide has 0.2 wt % to 1.3 wt % boron on an oil-free basis of the dispersant, and
the lubricating composition may be characterised as having (i) a sulphur content of 0.5 wt % or less, (ii) a phosphorus content of 0.1 wt % or less, and (iii) a sulphated ash content of 1.5 wt % or less.

In one embodiment the invention relates to a lubricating composition comprising:

an oil of lubricating viscosity,

2.3 wt % to 4 wt % of a dispersant package, wherein the dispersant package comprises:

a borated succinimide dispersant, wherein the borated succinimide dispersant may be obtained/obtainable by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and

a non-borated succinimide dispersant, wherein the non-borated succinimide dispersant may be obtained/obtainable by a “Diels-Alder” reaction of a polyalkylene with an acylating agent to form an intermediate, and reacting the intermediate with an aminoalcohol or amine to form a non-borated succinimide dispersant,

wherein
the ratio of non-borated succinimide dispersant to borated succinimide dispersant may be 90:10 to 20:80,
the borated succinimide has 0.2 wt % to 1.3 wt % boron on an oil-free basis of the dispersant, and
the lubricating composition may be characterised as having (i) a sulphur content of 0.5 wt % or less, (ii) a phosphorus content of 0.1 wt % or less, and (iii) a sulphated ash content of 1.5 wt % or less.

In one embodiment the invention relates to the use of the composition disclosed herein to provide at least one of improved fuel economy, reduced friction, reduced soot, reduced deposit formation, reduced wear and improved cleanliness for an internal combustion engine. Typically the use of the composition disclosed herein provides at least one of improved fuel economy and improved deposit control.

The dispersant package disclosed herein may be present at 2.5 wt % to 3 wt % of the lubricating composition.

The internal combustion engine disclosed herein may be a spark-ignited internal combustion engine. The internal combustion engine disclosed herein may be diesel or gasoline-fuelled (typically gasoline-fuelled).

### DETAILED DESCRIPTION OF THE INVENTION

The present invention provides a method for lubricating an internal combustion engine and a use as disclosed above.

### Dispersant Package

In one embodiment the acylating agent comprises/is maleic anhydride.

In one embodiment the polyalkylene comprises/is polyisobutylene.

The polyalkylene of both the borated succinimide and the non-borated succinimide may comprise a polyisobutylene having a polyisobutylene group having a number average molecular weight of 1550 to 2350, or 1950 to 2250.

In one embodiment the polyalkylene comprises/is polyisobutylene, and the acylating agent comprises/is maleic anhydride.

The borated succinimide and the non-borated succinimide may be prepared by reacting the polyalkylene and an acylating agent with an amine.

The amine may be aliphatic or cyclic. The amine may be a mono-amine or a polyamine. Typically the amine comprises an aliphatic polyamine, or mixtures thereof.

The aliphatic polyamine may be an alkylenepolyamine such as an ethylenepolyamine, propylenepolyamine, butylenepolyamine, or mixtures thereof. In one embodiment the aliphatic polyamine may be an ethylenepolyamine.

In one embodiment the aliphatic polyamine may be chosen from ethylenediamine, di ethylenetriamine, triethylenetetramine, tetraethylenepentamine, pentaethylenehexamine, polyamine still bottoms, and mixtures thereof.

The ratio of non-borated dispersant to borated dispersant may vary from 85:15 to 60:40, or 85:15 to 70:30.

### Non-Borated Dispersant

The non-borated polyisobutylene succinimide dispersants and their preparation are disclosed, for instance in U.S. Pat. Nos. 3,172,892, 3,219,666, 3,316,177, 3,340,281, 3,351,552, 3,381,022, 3,433,744, 3,444,170, 3,467,668, 3,501,405, 3,542,680, 3,576,743, 3,632,511, 4,234,435, Re 26,433, and U.S. Pat. Nos. 6,165,235, 7,238,650 and EP Patent Application 0 355 895 A.

It is well recognized by those skilled in the art of lubricant chemistry that there are two main ways to prepare a dispersant from a polyalkene and an acylating agent. The non-borated succinimide dispersant may be prepared from a polyalkene material such as polyisobutylene succinic anhydride (PIBSA) reacting with an acylating agent such as maleic anhydride and then reacted with an amine to form the non-borated succinimide dispersant. The reaction of the polyalkene and acylating agent (typically polyisobutylene and maleic anhydride) is described in the cited patent above and usually the reaction occurs in the presence of chlorine. This synthesis route typically forms a PIBSA, wherein the polyisobutylene is linked to a succinic anhydride moiety through a cyclic structure, as shown here:

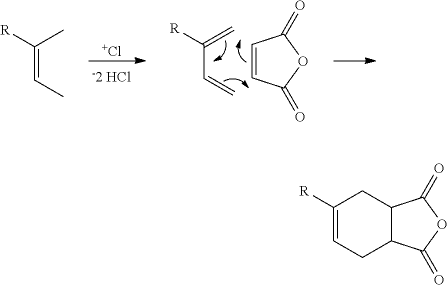

wherein R is the remainder of a polyalkene chain (typically a polyisobutylene chain).

The “chlorine route” for the preparation of the borated succinimide is discussed in Mortier et al., Chemistry and Technology of Lubricants, third edition, 2010, page 229.

The ratio of polyalkylene to acylating agent of the non-borated succinimide dispersant may be 1 to 1.05-2, or 1 to 1.1-1.8, or 1 to 1.25-1.7, or 1 to 1.4-1.6.

The ratio of nitrogen to carbonyl (N:CO) on an equivalent basis may vary from 0.5 to 1:1 to or 0.7 to 0.95:1 in the non-borated succinimide dispersant.

### Borated Succinimide

The borated dispersant may be prepared/obtained/obtainable from reaction of succinic anhydride by an “ene” reaction. The “ene” reaction mechanism and general reaction conditions are summarised in “Maleic Anhydride”, pages, 147-149, Edited by B. C. Trivedi and B. C. Culbertson and Published by Plenum Press in 1982.

The “ene” reaction may have a reaction temperature of 180° C. to less than 300° C., or 200° C. to 250° C., or 200° C. to 220° C.

The “ene” reaction between the polyalkylene and an acylating agent (typically polyisobutylene and maleic anhydride) may proceed via an “ene” reaction as is schematically drawn below. This “ene” reaction typically gives a product where the polyisobutylene is linked to a succinic anhydride moiety through a non-cyclic linkage, as illustrated here.

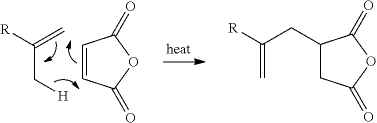

Wherein R group represents the remainder of the polyalkylene group.

The “ene” route for the preparation of the borated succinimide is discussed in Mortier et al., Chemistry and Technology of Lubricants, third edition, 2010, page 229.

Typically once formed a reaction product of polyalkylene, an acylating agent and an amine is further reacted with a borating agent to form a borated succinimide dispersant.

The borated succinimide may have 0.4 wt % to 0.6 wt % boron on an oil-free basis of the dispersant. In one embodiment the borating agent may include boric acid (including metaboric acid, HBO₂, orthoboric acid, H₃BO₃, and tetraboric acid, H₂B₄O₇), boric oxide, boron trioxide, and alkyl borates, such as those of the formula (RO)ₓB(OH)_{y}, wherein x may be 1 to 3 and y may be 0 to 2, the sum of x and y being 3, and where R may be an alkyl group containing 1 to 6 carbon atoms.

In one embodiment the borating agent may be boric acid.

The borated dispersant may be prepared by blending the boron compound and the N-substituted long chain alkenyl succinimides and heating them at a suitable temperature, such as, 80° C. to 250° C., or 90° C. to 230° C., or 100° C. to 210° C., until the desired reaction has occurred. An inert liquid may be used in performing the reaction. The liquid may include toluene, xylene, chlorobenzene, dimethylformamide, diluent oil or mixtures thereof.

The borated succinimide may have 0.35 wt % to 0.95 wt % boron on an oil-free basis of the dispersant.

In different embodiments the ratio of polyalkylene to acylating agent of the borated succinimide dispersant may be 1 to 1.05-2, or 1 to 1.1-1.8, or 1 to 1.25-1.7, or 1 to 1.4-1.6.

The borated succinimide dispersant may have a N:CO ratio of 0.5 to 1:1 or 0.7 to 0.95:1.

### Oils of Lubricating Viscosity

The lubricating composition comprises an oil of lubricating viscosity. Such oils include natural and synthetic oils, oil derived from hydrocracking, hydrogenation, and hydrofinishing, unrefined, refined, re-refined oils or mixtures thereof. A more detailed description of unrefined, refined and re-refined oils is provided in International Publication WO2008/147704, paragraphs [0054] to [0056] (a similar disclosure is provided in US Patent Application 2010/197536, see [0072] to [0073]). A more detailed description of natural and synthetic lubricating oils is described in paragraphs [0058] to [0059] respectively of WO2008/147704 (a similar disclosure is provided in US Patent Application 2010/197536, see [0075] to [0076]). Synthetic oils may also be produced by Fischer-Tropsch reactions and typically may be hydroisomerised Fischer-Tropsch hydrocarbons or waxes. In one embodiment oils may be prepared by a Fischer-Tropsch gas-to-liquid synthetic procedure as well as other gas-to-liquid oils.

Oils of lubricating viscosity may also be defined as specified in April 2008 version of “Appendix E—API Base Oil Interchangeability Guidelines for Passenger Car Motor Oils and Diesel Engine Oils”, section 1.3 Sub-heading 1.3. “Base Stock Categories”. The API Guidelines are also summarised in US Patent U.S. Pat. No. 7,285,516 (see column 11, line 64 to column 12, line 10).

In one embodiment the oil of lubricating viscosity may be an API Group I to IV mineral oil, an ester or a synthetic oil, or mixtures thereof. In one embodiment the oil of lubricating viscosity may be an API Group II, Group III, Group IV mineral oil, an ester or a synthetic oil, or mixtures thereof.

The amount of the oil of lubricating viscosity present is typically the balance remaining after subtracting from 100 wt % the sum of the amount of the additives of the invention and the other performance additives.

The lubricating composition may be in the form of a concentrate and/or a fully formulated lubricant. If the lubricating composition of the invention (comprising the additives disclosed herein) is in the form of a concentrate which may be combined with additional oil to form, in whole or in part, a finished lubricant), the ratio of the of these additives to the oil of lubricating viscosity and/or to diluent oil include the ranges of 1:99 to 99:1 by weight, or 80:20 to 10:90 by weight. Typically the lubricating composition of the invention comprises at least 50 wt %, or at least 60 wt %, or at least 70 wt %, or at least 80 wt % of an oil of lubricating viscosity.

### Other Performance Additives

A lubricating composition may be prepared by adding the product of the process described herein to an oil of lubricating viscosity, optionally in the presence of other performance additives (as described herein below).

The lubricating composition of the invention optionally comprises other performance additives. The other performance additives include at least one of detergents, metal deactivators, viscosity modifiers, viscosity modifiers, friction modifiers, antiwear agents, corrosion inhibitors, extreme pressure agents, antioxidants, foam inhibitors, demulsifiers, pour point depressants, seal swelling agents and mixtures thereof. Typically, fully-formulated lubricating oil will contain one or more of these performance additives.

In one embodiment the invention provides a lubricating composition further comprising an overbased metal-containing detergent. The metal of the metal-containing detergent may be zinc, sodium, calcium, barium, or magnesium. Typically the metal of the metal-containing detergent may be sodium, calcium, or magnesium.

The overbased metal-containing detergent may be chosen from non-sulphur containing phenates, sulphur containing phenates, sulphonates, salixarates, salicylates, and mixtures thereof, or borated equivalents thereof. The overbased detergent may be borated with a borating agent such as boric acid.

The overbased metal-containing detergent may also include “hybrid” detergents formed with mixed surfactant systems including phenate and/or sulphonate components, e.g. phenate/salicylates, sulphonate/phenates, sulphonate/salicylates, sulphonates/phenates/salicylates, as described; for example, in U.S. Pat. Nos. 6,429,178; 6,429,179; 6,153,565; and 6,281,179. Where, for example, a hybrid sulphonate/phenate detergent is employed, the hybrid detergent would be considered equivalent to amounts of distinct phenate and sulphonate detergents introducing like amounts of phenate and sulphonate soaps, respectively.

Typically an overbased metal-containing detergent may be a zinc, sodium, calcium or magnesium salt of a phenate, sulphur containing phenate, sulphonate, salixarate or salicylate. Overbased salixarates, phenates and salicylates typically have a total base number of 180 to 450 TBN. Overbased sulphonates typically have a total base number of 250 to 600, or 300 to 500. Overbased detergents are known in the art. In one embodiment the sulphonate detergent may be a predominantly linear alkylbenzene sulphonate detergent having a metal ratio of at least 8 as is described in paragraphs [0026] to [0037] of US Patent Application 2005065045 (and granted as U.S. Pat. No. 7,407,919). The predominantly linear alkylbenzene sulphonate detergent may be particularly useful for assisting in improving fuel economy.

Typically the overbased metal-containing detergent may be a calcium or magnesium an overbased detergent.

Overbased detergents are known in the art. Overbased materials, otherwise referred to as overbased or superbased salts, are generally single phase, homogeneous Newtonian systems characterized by a metal content in of that which would be present for neutralization according to the stoichiometry of the metal and the particular acidic organic compound reacted with the metal. The overbased materials are prepared by reacting an acidic material (typically an inorganic acid or lower carboxylic acid, preferably carbon dioxide) with a mixture comprising an acidic organic compound, a reaction medium comprising at least one inert, organic solvent (mineral oil, naphtha, toluene, xylene, etc.) for said acidic organic material, a stoichiometric excess of a metal base, and a promoter such as a calcium chloride, acetic acid, phenol or alcohol. The acidic organic material will normally have a sufficient number of carbon atoms to provide a degree of solubility in oil. The amount of “excess” metal (stoichiometrically) is commonly expressed in terms of metal ratio. The term “metal ratio” is the ratio of the total equivalents of the metal to the equivalents of the acidic organic compound. A neutral metal salt has a metal ratio of one. A salt having 3.5 times as much metal as present in a normal salt will have metal excess of 3.5 equivalents, or a ratio of 4.5. The term “metal ratio is also explained in standard textbook entitled “Chemistry and Technology of Lubricants”, Third Edition, Edited by R. M. Mortier and S. T. Orszulik, Copyright 2010, page 219, sub-heading 7.25.

In one embodiment the lubricating composition further comprises a calcium sulphonate overbased detergent and a calcium phenate overbased detergent in an amount such that the sulphated ash content may be 1000 ppm or less (such as 100 ppm to 1000 ppm, or 300 ppm to 900 ppm).

The lubricating composition in a further embodiment comprises an antioxidant, wherein the antioxidant comprises a phenolic or an aminic antioxidant or mixtures thereof. The antioxidants include diarylamines, alkylated diarylamines, hindered phenols, or mixtures thereof. When present the antioxidant may be present at 0.1 wt % to 3 wt %, or 0.5 wt % to 2.75 wt %, or 1 wt % to 2.5 wt % of the lubricating composition.

The diarylamine or alkylated diarylamine may be a phenyl-α-naphthylamine (PANA), an alkylated diphenylamine, or an alkylated phenylnapthylamine, or mixtures thereof. The alkylated diphenylamine may include di-nonylated diphenylamine, nonyl diphenyl amine, octyl diphenyl amine, di-octylated diphenyl amine, di-decylated diphenylamine, decyl diphenylamine and mixtures thereof. In one embodiment the diphenylamine may include nonyl diphenylamine, dinonyl diphenylamine, octyl diphenylamine, dioctyl diphenylamine, or mixtures thereof. In another embodiment the alkylated diphenylamine may include nonyl diphenylamine, or dinonyl diphenylamine. The alkylated diarylamine may include octyl, di-octyl, nonyl, di-nonyl, decyl or di-decyl phenylnapthylamines.

The hindered phenol antioxidant often contains a secondary butyl and/or a tertiary butyl group as a sterically hindering group. The phenol group may be further substituted with a hydrocarbyl group (typically linear or branched alkyl) and/or a bridging group linking to a second aromatic group. Examples of suitable hindered phenol antioxidants include 2,6-di-tert-butylphenol, 4-methyl-2,6-di-tert-butylphenol, 4-ethyl-2,6-di-tert-butylphenol, 4-propyl-2,6-di-tert-butylphenol or 4-butyl-2,6-di-tert-butylphenol, or 4-dodecyl-2,6-di-tert-butyl-phenol. In one embodiment the hindered phenol antioxidant may be an ester and may include, e.g., Irganox™ L-135 from Ciba. A more detailed description of suitable ester-containing hindered phenol antioxidant chemistry is found in U.S. Pat. No. 6,559,105.

In one embodiment the friction modifier may be chosen from long chain fatty acid derivatives of amines, long chain fatty esters, or derivatives of long chain fatty epoxides; fatty imidazolines; amine salts of alkylphosphoric acids; fatty alkyl tartrates; fatty alkyl tartrimides; fatty alkyl tartramides; fatty glycolates; and fatty glycolamides. The friction modifier may be present at 0 wt % to 6 wt %, or 0.01 wt % to 4 wt %, or 0.05 wt % to 2 wt %, or 0.1 wt % to 2 wt % of the lubricating composition.

As used herein the term “fatty alkyl” or “fatty” in relation to friction modifiers means a carbon chain having 10 to 22 carbon atoms, typically a straight carbon chain.

Examples of suitable friction modifiers include long chain fatty acid derivatives of amines, fatty esters, or fatty epoxides; fatty imidazolines such as condensation products of carboxylic acids and polyalkylene-polyamines; amine salts of alkylphosphoric acids; fatty alkyl tartrates; fatty alkyl tartrimides; fatty alkyl tartramides; fatty phosphonates; fatty phosphites; borated phospholipids, borated fatty epoxides; glycerol esters; borated glycerol esters; fatty amines; alkoxylated fatty amines; borated alkoxylated fatty amines; hydroxyl and polyhydroxy fatty amines including tertiary hydroxy fatty amines; hydroxy alkyl amides; metal salts of fatty acids; metal salts of alkyl salicylates; fatty oxazolines; fatty ethoxylated alcohols; condensation products of carboxylic acids and polyalkylene polyamines; or reaction products from fatty carboxylic acids with guanidine, aminoguanidine, urea, or thiourea and salts thereof.

Friction modifiers may also encompass materials such as sulphurised fatty compounds and olefins, molybdenum dialkyldithiophosphates, molybdenum dithiocarbamates, sunflower oil or soybean oil monoester of a polyol and an aliphatic carboxylic acid.

In another embodiment the friction modifier may be a long chain fatty acid ester. In another embodiment the long chain fatty acid ester may be a mono-ester and in another embodiment the long chain fatty acid ester may be a triglyceride.

The lubricating composition optionally further includes at least one antiwear agent. Examples of suitable antiwear agents include titanium compounds, tartrates, tartrimides, oil soluble amine salts of phosphorus compounds, sulphurised olefins, metal dihydrocarbyldithiophosphates (such as zinc dialkyldithiophosphates), phosphites (such as dibutyl phosphite), phosphonates, thiocarbamate-containing compounds, such as thiocarbamate esters, thiocarbamate amides, thiocarbamic ethers, alkylene-coupled thio-carbamates, and bis(S-alkyldithiocarbamyl) disulphides.

The antiwear agent may in one embodiment include a tartrate, or tartrimide as disclosed in International Publication WO 2006/044411 or Canadian Patent CA 1 183 125. The tartrate or tartrimide may contain alkyl-ester groups, where the sum of carbon atoms on the alkyl groups is at least 8. The antiwear agent may in one embodiment include a citrate as is disclosed in US Patent Application 20050198894.

Another class of additives includes oil-soluble titanium compounds as disclosed in U.S. Pat. No. 7,727,943 and US2006/0014651. The oil-soluble titanium compounds may function as antiwear agents, friction modifiers, antioxidants, deposit control additives, or more than one of these functions. In one embodiment the oil soluble titanium compound may be a titanium (IV) alkoxide. The titanium alkoxide may be formed from a monohydric alcohol, a polyol or mixtures thereof. The monohydric alkoxides may have 2 to 16, or 3 to 10 carbon atoms. In one embodiment, the titanium alkoxide may be titanium (IV) isopropoxide. In one embodiment, the titanium alkoxide may be titanium (IV) 2-ethylhexoxide. In one embodiment, the titanium compound comprises the alkoxide of a vicinal 1,2-diol or polyol. In one embodiment, the 1,2-vicinal diol comprises a fatty acid mono-ester of glycerol, often the fatty acid may be oleic acid.

In one embodiment, the oil soluble titanium compound may be a titanium carboxylate. In a further embodiment the titanium (IV) carboxylate may be titanium neodecanoate.

The lubricating composition may in one embodiment further include a phosphorus-containing antiwear agent. Typically the phosphorus-containing antiwear agent may be a zinc dialkyldithiophosphate, phosphite, phosphate, phosphonate, and ammonium phosphate salts, or mixtures thereof. Zinc dialkyldithiophosphates are known in the art. The antiwear agent may be present at 0 wt % to 3 wt %, or 0.1 wt % to 1.5 wt %, or 0.5 wt % to 0.9 wt % of the lubricating composition.

The viscosity modifier is known in the art and may include hydrogenated styrene-butadiene rubbers, ethylene-propylene copolymers, polymethacrylates, polyacrylates, hydrogenated styrene-isoprene polymers, hydrogenated diene polymers, polyalkyl styrenes, polyolefins, esters of maleic anhydride-olefin copolymers (such as those described in International Application WO 2010/014655), esters of maleic anhydride-styrene copolymers, or mixtures thereof.

The lubricating composition of the invention in one embodiment further contains a dispersant viscosity modifier. When present the viscosity modifier, and/or dispersant viscosity modifier may be present at 0.05 wt % to 1.5 wt %, or 0.1 wt % to 1 wt %, or 0.1 to 0.7 wt %.

The dispersant viscosity modifier may include functionalised polyolefins, for example, ethylene-propylene copolymers that have been functionalised with an acylating agent such as maleic anhydride and an amine; polymethacrylates functionalised with an amine, or styrene-maleic anhydride copolymers reacted with an amine. More detailed description of dispersant viscosity modifiers are disclosed in International Publication WO2006/015130 or

U.S. Pat. Nos. 4,863,623; 6,107,257; 6,107,258; 6,117,825; and U.S. Pat. No. 7,790,661. In one embodiment the dispersant viscosity modifier may include those described in U.S. Pat. No. 4,863,623 (see column 2, line 15 to column 3, line 52) or in International Publication WO2006/015130 (see page 2, paragraph [0008] and preparative examples are described paragraphs [0065] to [0073]).

Extreme Pressure (EP) agents that are soluble in the oil include sulphur- and chlorosulphur-containing EP agents, dimercaptothiadiazole or CS₂ derivatives of dispersants (typically succinimide dispersants), derivative of chlorinated hydrocarbon EP agents and phosphorus EP agents. Examples of such EP agents include chlorinated wax; sulphurised olefins (such as sulphurised isobutylene), a hydrocarbyl-substituted 2,5-dimercapto-1,3,4-thiadiazole, or oligomers thereof, organic sulphides and polysulphides such as dibenzyldisulphide, bis-(chlorobenzyl) disulphide, dibutyl tetrasulphide, sulphurised methyl ester of oleic acid, sulphurised alkylphenol, sulphurised dipentene, sulphurised terpene, and sulphurised Diels-Alder adducts; phosphosulphurised hydrocarbons such as the reaction product of phosphorus sulphide with turpentine or methyl oleate; phosphorus esters such as the dihydrocarbon and trihydrocarbon phosphites, e.g., dibutyl phosphite, diheptyl phosphite, dicyclohexyl phosphite, pentylphenyl phosphite; dipentylphenyl phosphite, tridecyl phosphite, distearyl phosphite and polypropylene substituted phenol phosphite; metal thiocarbamates such as zinc dioctyldithiocarbamate and barium heptylphenol diacid; amine salts of alkyl and dialkylphosphoric acids or derivatives including, for example, the amine salt of a reaction product of a dialkyldithiophosphoric acid with propylene oxide and subsequently followed by a further reaction with P₂O₅; and mixtures thereof (as described in U.S. Pat. No. 3,197,405).

Foam inhibitors that may be useful in the compositions of the invention include polysiloxanes, copolymers of ethyl acrylate and 2-ethylhexylacrylate and optionally vinyl acetate; demulsifiers including fluorinated polysiloxanes, trialkyl phosphates, polyethylene glycols, polyethylene oxides, polypropylene oxides and (ethylene oxide-propylene oxide) polymers.

Pour point depressants that may be useful in the compositions of the invention include polyalphaolefins, esters of maleic anhydride-styrene copolymers, poly(meth)acrylates, polyacrylates or polyacrylamides.

Demulsifiers include trialkyl phosphates, and various polymers and copolymers of ethylene glycol, ethylene oxide, propylene oxide, or mixtures thereof.

Metal deactivators include derivatives of benzotriazoles (typically tolyltriazole), 1,2,4-triazoles, benzimidazoles, 2-alkyldithiobenzimidazoles or 2-alkyldithiobenzothiazoles. The metal deactivators may also be described as corrosion inhibitors. XXSeal swell agents include sulfolene derivatives Exxon Necton-37™ (FN 1380) and Exxon Mineral Seal Oil™ (FN 3200).

### INDUSTRIAL APPLICATION

The internal combustion engine may be a 4-stroke engine. The internal combustion engine may or may not have an Exhaust Gas Recirculation system. The internal combustion engine may be fitted with an emission control system or a turbocharger. Examples of the emission control system include diesel particulate filters (DPF), or systems employing selective catalytic reduction (SCR).

The lubricating composition may be characterised as having (i) a sulphur content of 0.5 wt % or less, (ii) a phosphorus content of 0.1 wt % or less, and (iii) a sulphated ash content of 0.5 wt % to 1.5 wt % or less.

The lubricating composition may be characterised as having at least one of (i) a sulphur content of 0.2 wt % to 0.4 wt % or less, (ii) a phosphorus content of 0.08 wt % to 0.15 wt %, and (iii) a sulphated ash content of 0.5 wt % to 1.5 wt % or less.

The lubricating composition may be characterised as having a sulphated ash content of 0.5 wt % to 1.2 wt %.

The lubricating composition may have a total sulphated ash content of 1.2 wt % or less.

The sulphur content of the lubricating composition may be 1 wt % or less, or 0.8 wt % or less, or 0.5 wt % or less, or 0.3 wt % or less. In one embodiment the sulphur content may be in the range of 0.001 wt % to 0.5 wt %, or 0.01 wt % to 0.3 wt %. The phosphorus content may be 0.2 wt % or less, or 0.12 wt % or less, or 0.1 wt % or less, or 0.085 wt % or less, or 0.08 wt % or less, or even 0.06 wt % or less, 0.055 wt % or less, or 0.05 wt % or less. In one embodiment the phosphorus content may be 0.04 wt % to 0.12 wt %. In one embodiment the phosphorus content may be 100 ppm to 1000 ppm, or 200 ppm to 600 ppm. The total sulphated ash content may be 0.3 wt % to 1.2 wt %, or 0.5 wt % to 1.1 wt % of the lubricating composition. In one embodiment the sulphated ash content may be 0.5 wt % to 1.1 wt % of the lubricating composition.

In one embodiment the lubricating composition may be characterised as having (i) a sulphur content of 0.5 wt % or less, (ii) a phosphorus content of 0.15 wt % or less, and (iii) a sulphated ash content of 0.5 wt % to 1.5 wt % or less.

The lubricating composition may be characterised as having at least one of (i) a sulphur content of 0.2 wt % to 0.4 wt % or less, (ii) a phosphorus content of 0.08 wt % to 0.15 wt %, and (iii) a sulphated ash content of 0.5 wt % to 1.5 wt % or less.

The lubricating composition may be characterised as having a sulphated ash content of 0.5 wt % to 1.2 wt %.

As used herein TBN values are (total base number) measured by the methodology described in ASTM D4739 (buffer).

The lubricating composition may be characterized as having a total base number (TBN) content of at least 5 mg KOH/g.

The lubricating composition may be characterized as having a total base number (TBN) content of 6 to 13 mg KOH/g, or 7 to 12 mg KOH/g.

The lubricating composition may have a SAE viscosity grade of XW-Y, wherein X may be 0, 5, 10, or 15; and Y may be 16, 20, 30, or 40.

The internal combustion engine disclosed herein may have a steel surface on a cylinder bore, cylinder block, or piston ring.

The internal combustion engine may have a surface of steel, or an aluminium alloy, or an aluminium composite.

The following examples provide illustrations of the invention. These examples are non-exhaustive and are not intended to limit the scope of the invention.

### EXAMPLES

Preparative Example 1 (PREP EX1); Boron-containing dispersant made by chlorine-assisted process—A 2 L four-necked flask equipped with a mechanical overhead stirrer, thermowell, subsurface nitrogen inlet with attached addition funnel, and a Dean Stark trap with attached condenser was charged with succinated polyisobutylene (PIBSA), prepared by a Diels Alder (may also be referred to as Cl-process) reaction between a chlorinated low-vinylidene polyisobutylene (<10 mol % terminal vinylidene) and maleic anhydride to produce PIBSA with 1.58 diacid groups per polymer, (500.0 g, 0.643 eq. CO) and diluent oil (458.8 g, 47% wt) and heated to 110° C. The addition funnel was charged with polyethylene polyamine bottoms (PEPA) (purchased from Dow Chemical as Heavy Polyamine X, i.e. HPA-X) (23.2 g, 0.559 eq. N) and added to the reaction mixture over 30 min. Upon addition of PEPA, the addition funnel was removed and the reaction mixture was heated to 155° C. and allowed to stir for 5 h. The reaction mixture was filtered to give the product as a viscous amber oil (94%). The product formed as a nitrogen content of 0.8 wt %, and a boron content of 0 wt %, and 47 wt % diluent oil.

Preparative Example 2 (PREP EX2); Boron-free dispersant made by thermal “ene” process—A 2 L four-necked flask equipped with a mechanical overhead stirrer, thermowell, subsurface nitrogen inlet with attached addition funnel, and a Dean Stark trap with attached condenser was charged with succinated polyisobutylene (PIBSA), prepared by thermal reaction of polyisobutylene (2000 Mn and terminal vinylidene content of 80-90%) with enough maleic anhydride to produce PIBSA with ˜1.55 diacid groups per polymer, (500.0 g, 0.626 eq. CO) and diluent oil (345.0 g, 40% wt) and heated to 110° C. The addition funnel was charged with PEPA polyamine (as described in PREP EX1 above) (23.1 g, 0.557 eq. N) and added to the reaction mixture over 30 min. Upon addition of the polyamine, the addition funnel was removed and the reaction mixture was heated to 155° C. and allowed to stir for 5 h. The reaction mixture was filtered to give the product as a viscous amber oil (93%). The product formed as a nitrogen content of 0.9 wt %, and a boron content of 0 wt %, and 40 wt % diluent oil.

Preparative Example 3 (PREP EX3); Borated dispersant made by thermal “ene process —A 2 L four-necked flask equipped with a mechanical overhead stirrer, thermowell, subsurface nitrogen inlet with attached addition funnel, and a Dean Stark trap with attached condenser was charged with the PIBSA from PREP EX2 above (500.0 g, 0.626 eq. CO) and diluent oil (345.2 g, 39.3% wt) and heated to 110° C. The addition funnel was charged with PEPA polyamine (as described in PREP EX1 above) (22.0 g, 0.532 eq. N) and added to the reaction mixture over 30 min. Upon addition of PEPA, the addition funnel was removed and the reaction mixture was heated to 155° C. and allowed to stir for 5 h. The reaction mixture was cooled to 90° C. and Boric acid (23.6 g, 0.382 eq. B) was added in a single portion to the flask. The mixture was heated to 155° C. and allowed to stir for an additional 5 h. The reaction mixture was filtered to give the product as a viscous amber oil (92%) The product formed as a nitrogen content of 0.85 wt %, and a boron content of 0.47wt %, and 39.3 wt % diluent oil.

Preparative Example 4 (PREP EX4); Borated dispersant made by thermal “ene process—A 2 L four-necked flask equipped with a mechanical overhead stirrer, thermowell, subsurface nitrogen inlet with attached addition funnel, and a Dean Stark trap with attached condenser was charged with the PIBSA from PREP EX2 above, (500.0 g, 0.626 eq. CO) and diluent oil (527.7 g, 48.5% wt) and heated to 110° C. The addition funnel was charged with PEPA (as described in PREP EX1 above) (35.0 g, 0.845 eq. N) and added to the reaction mixture over 30 min. Upon addition of PHPA, the addition funnel was removed and the reaction mixture was heated to 155° C. and allowed to stir for 5 h. The reaction mixture was cooled to 90° C. and boric acid (43.7 g, 0.707 eq. B) was added in a single portion to the flask. The mixture was heated to 155° C. and allowed to stir for an additional 5 h. Filter aid (10 g, 1% wt) was added to the reaction flask and the reaction mixture was passed through a cloth filter containing additional filter aid (20 g, 2% wt) to give the product as a viscous amber oil (90%). The product formed as a nitrogen content of 0.1.1 wt %, and a boron content of 0.7 wt %, and 48.5 wt % diluent oil. The preparative examples are summarized in Table 1.

TABLE 1
Preparative Dispersant Examples

| | PREP EX1 | PREP EX2 | PREP EX3 | PREP EX4 |
|---|---|---|---|---|
| Method | Cl-process | Thermal ene | Thermal ene | Thermal ene |
| PIB Mn | 2000 | 2000 | 2000 | 2000 |
| Deg. Succ.¹ | 1.58 | 1.55 | 1.55 | 1.55 |
| % N | 0.8 | 0.9 | 0.85 | 1.1 |
| N:CO (mol) | 0.87 | 0.89 | 0.85 | 1.35 |
| % B | 0 | 0 | 0.47 | 0.70 |
| B:N (mol) | 0 | 0 | 0.72 | 0.84 |
| % Oil | 47 | 40 | 39.3 | 48.5 |

¹Average number of succinic anhydride groups per polyisobutylene chain, i.e. ratio of polyalkylene to acylating agent

A series of lubricating compositions are prepared Comparative Examples 1-3 (CE1-CE3), and Inventive Examples 1-5 (IC1-IC5 respectively) in API Group III base oil. The amounts of all additives included within each example are on an actives basis. All inventive and comparative examples comprise a mixture of 0.91 wt % of a combination of calcium and sodium overbased alkylbenzenesulfonate detergents, 1.2 wt % of a combination of aminic and phenolic antioxidants, 0.14 wt % of a polymethacrylate pour point depressant, 0.79 wt % of zinc dialkyldithiophosphate, 0.6 wt % of an ethylene-propylene copolymer viscosity modifier, and anti-foam agent. Inventive examples IC3 and IC4 also contain 0.5 wt % of a friction modifier composition. Each lubricant also contains dispersant additives as presented below in Table 2:

TABLE 2
Dispersant Additives in Lubricating Compositions

| | Lubricating Compositions | | | |
|---|---|---|---|---|
| | PREP EX1 | PREP EX2 | PREP EX3 | PREP EX4 |
| CE1 | 2.9 | 0 | 0 | 0 |
| CE2 | 0 | 2.9 | 0 | 0 |
| CE3¹ | 2.0 | 0 | 0 | 0 |
| IC1 | 2.32 | 0 | 0.58 | 0 |
| IC2 | 2.32 | 0 | 0 | 0.58 |
| IC3 | 2.32 | 0 | 0.58 | 0 |
| IC4 | 2.32 | 0 | 0 | 0.58 |
| IC5¹ | 2.32 | 0 | 0 | 0.58 |

¹Contain 1.8 wt % organic antioxidants (phenolic and aryl amine)

Each lubricant is evaluated in Sequence VID fuel economy test and FEI1 and FEI2 results are reported. FEI1 and FEI2 are measures of the fresh oil and aged oil fuel economy of the lubricant respectively. The results are reported as a percent improvement over an industry standard baseline fluid as described in ASTM D7589. Higher FEI1 and FEI2 indicate improved fuel economy. The results obtained are summarized in Table 3:

TABLE 3
Fuel Economy Testing

| Lubricant | FEI1 | FEI2 |
|---|---|---|
| CE1 | 0.89 | 0.55 |
| CE2 | 0.27 | Not Run* |
| IC1 | 0.89 | 0.58 |
| IC2 | 0.67 | 0.56 |
| IC3 | 1.1 | 0.77 |
| IC4 | 0.82 | 0.73 |

*Test terminated because of poor FEI1 result

The data demonstrates that the lubricating composition defined by the present invention has equivalent or improved fuel economy over comparative lubricants evaluated in the Sequence VID test.

The lubricating compositions are also evaluated in the Sequence IIIG oxidation/deposit engine test (ASTM D7320). This test is designed to measure the ability of an oil to control piston deposits (average weighted piston deposits WPD), prevent wear (cam and lifter), and control viscosity increase and oil consumption when an engine is operated at very high speeds and loads.

TABLE 4
Oxidation/Deposit Testing

| | | % Vis | |
|---|---|---|---|
| Lubricant | WPD | Increase | Cam + Lifter Wear (□m) |
| CE3 | 3.6 | 102 | 34.6 |
| IC5 | 5.2 | 270 | 22.8 |

The data demonstrates that a formulation of the invention containing both a conventional (chlorine-process) dispersant and a borated thermal “ene” dispersant (made from high vinylidene polyisobutylene) provides improved deposit control without sacrificing fuel economy performance.

It is known that some of the materials described above may interact in the final formulation, so that the components of the final formulation may be different from those that are initially added. The products formed thereby, including the products formed upon employing lubricant composition of the present invention in its intended use, may not be susceptible of easy description. Nevertheless, all such modifications and reaction products are included within the scope of the present invention; the present invention encompasses lubricant composition prepared by admixing the components described above.

Each of the documents referred to above is incorporated herein by reference. Except in the Examples, or where otherwise explicitly indicated, all numerical quantities in this description specifying amounts of materials, reaction conditions, molecular weights, number of carbon atoms, and the like, are to be understood as modified by the word “about.” Unless otherwise indicated, each chemical or composition referred to herein should be interpreted as being a commercial grade material which may contain the isomers, by-products, derivatives, and other such materials which are normally understood to be present in the commercial grade. However, the amount of each chemical component is presented exclusive of any solvent or diluent oil, which may be customarily present in the commercial material, unless otherwise indicated. It is to be understood that the upper and lower amount, range, and ratio limits set forth herein may be independently combined. Similarly, the ranges and amounts for each element of the invention may be used together with ranges or amounts for any of the other elements.

As used herein, the term “hydrocarbyl substituent” or “hydrocarbyl group” is used in its ordinary sense, which is well-known to those skilled in the art. Specifically, it refers to a group having a carbon atom directly attached to the remainder of the molecule and having predominantly hydrocarbon character. Examples of hydrocarbyl groups include: hydrocarbon substituents, including aliphatic, alicyclic, and aromatic substituents; substituted hydrocarbon substituents, that is, substituents containing non-hydrocarbon groups which, in the context of this invention, do not alter the predominantly hydrocarbon nature of the substituent; and hetero substituents, that is, substituents which similarly have a predominantly hydrocarbon character but contain other than carbon in a ring or chain. A more detailed definition of the term “hydrocarbyl substituent” or “hydrocarbyl group” is described in paragraphs [0118] to [0119] of International Publication WO2008147704, or a similar definition in paragraphs [0137] to [0141] of published application US 2010-0197536.

As described hereinafter the number average molecular weight of the dispersant viscosity modifier and viscosity modifier has been determined using known methods, such as GPC analysis using polystyrene standards. Methods for determining molecular weights of polymers are well known. The methods are described for instance: (i) P. J. Flory, “Principles of Polymer Chemistry”, Cornell University Press 91953), Chapter VII, pp 266-315; or (ii) “Macromolecules, an Introduction to Polymer Science”, F. A. Bovey and F. H. Winslow, Editors, Academic Press (1979), pp 296-312.

While the invention has been explained in relation to its preferred embodiments, it is to be understood that various modifications thereof will become apparent to those skilled in the art upon reading the specification. Therefore, it is to be understood that the invention disclosed herein is intended to cover such modifications as fall within the scope of the appended claims.

What is claimed is:

1. A method of lubricating an internal combustion engine comprising supplying to the engine a lubricating composition comprising:
an oil of lubricating viscosity,
2.3 wt % to 4 wt % of a dispersant package, wherein the dispersant package comprises:
a borated succinimide dispersant, wherein the borated succinimide dispersant is obtained by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and
a non-borated succinimide dispersant, wherein the non-borated succinimide dispersant is obtained by a “Diels-Alder” reaction of a polyalkylene with an acylating agent to form an intermediate, and reacting the intermediate with an aminoalcohol or amine to form a non-borated succinimide dispersant, wherein t
he ratio of non-borated succinimide dispersant to borated succinimide dispersant is 90:10 to 20:80, and
the borated succinimide dispersant has 0.2 wt % to 1.3 wt % boron on an oil-free basis of the borated succinimide dispersant.

2. The method of claim 1, wherein the borated succinimide dispersant has 0.35 wt % to 0.95 wt % boron on an oil-free basis of the borated succinimide dispersant.

3. The method of claim 2, wherein the borated succinimide has 0.4 wt % to 0.6 wt % boron on an oil-free basis of the dispersant.

4. The method of claim 1, wherein the borating agent comprises boric acid (including metaboric acid, HBO₂, orthoboric acid, H₃BO₃, and tetraboric acid, H₂B₄O₇), boric oxide, boron trioxide, and alkyl borates, such as those of the formula (RO)ₓB(OH)_{y} wherein x is 1 to 3 and y is 0 to 2, the sum of x and y being 3, and where R is an alkyl group containing 1 to 6 carbon atoms.

5. The method of claim 4, wherein the borating agent is boric acid.

6. The method of claim 1, wherein the dispersant package is present at 2.5 wt % to 3 wt % of the lubricating composition.

7. The method of claim 1, wherein the amine comprises an aliphatic polyamine, or mixtures thereof.

8. The method of claim 7, wherein the aliphatic polyamine is selected from the group consisting of ethylenediamine, diethylenetriamine, triethylenetetramine, tetraethylenepentamine, pentaethylenehexamine, polyamine still bottoms, and mixtures thereof.

9. The method of claim 1, wherein the ratio of non-borated dispersant to borated dispersant is 85:15 to 60:40.

10. The method of claim 1, wherein the acylating agent comprises maleic anhydride.

11. The method of claim 1, wherein the polyalkylene comprises polyisobutylene having a number average molecular weight of 1550 to 2350.

12. The method of claim 1, wherein the ratio of polyalkylene to acylating agent of the borated succinimide dispersant is 1:1.05 to 1:2.

13. The method of claim 1, wherein the ratio of polyalkylene to acylating agent of the non-borated succinimide dispersant is 1:1.05 to 1:2.

14. The method of claim 1, wherein the borated succinimide dispersant has an N:CO ratio on a equivalents basis of 0.5:1 to 1:1.

15. The method of claim 1, wherein the non-borated succinimide dispersant has an N:CO ratio on a equivalents basis of 0.5:1 to 1:1.

16. The method of claim 1, wherein the lubricating composition has a SAE viscosity grade of XW-Y, wherein X is 0, 5, 10, or 15; and Y is 16, 20, 30, or 40.

17. The method of claim 1, wherein the lubricating composition has (i) a sulphur content of 0.5 wt % or less, (ii) a phosphorus content of 0.1 wt % or less, and (iii) a sulphated ash content of 1.5 wt % or less.

18. The method of claim 1, wherein the internal combustion engine is a spark-ignited internal combustion engine.

19. The method of claim 1, wherein the internal combustion engine is gasoline-fueled.

20. A method of lubricating an internal combustion engine comprising supplying to the engine a lubricating composition comprising:
an oil of lubricating viscosity,
2.3 wt % to 4 wt % of a dispersant package, wherein the dispersant package comprises:
a borated succinimide dispersant, wherein the borated succinimide dispersant comprises a non-cyclic linkage between a polyalkylene and an acylating agent,
a non-borated succinimide dispersant, wherein the non-borated succinimide dispersant comprises a carbocyclic linkage between a polyalkylene and an acylating agent, wherein
the ratio of non-borated succinimide dispersant to borated succinimide dispersant is 90:10 to 20:80, and
the borated succinimide dispersant has 0.2 wt % to 1.3 wt % boron on an oil-free basis of the borated succinimide dispersant.

21. A lubricating composition comprising:
an oil of lubricating viscosity, 2.3 wt % to 4 wt % of a dispersant package, wherein the dispersant package comprises:
a borated succinimide dispersant, wherein the borated succinimide dispersant comprises a non-cyclic linkage between a polyalkylene and an acylating agent,
a non-borated succinimide dispersant, wherein the non-borated succinimide dispersant comprises a carbocyclic linkage between a polyalkylene and an acylating agent,
wherein
the ratio of non-borated succinimide dispersant to borated succinimide dispersant is 90:10 to 20:80,
the borated succinimide has 0.2 wt % to 1.3 wt % boron on an oil-free basis of the dispersant, and
the lubricating composition is characterized as having (i) a sulphur content of 0.5 wt % or less, (ii) a phosphorus content of 0.1 wt % or less, and (iii) a sulphated ash content of 1.5 wt % or less.

22. The lubricating composition of claim 21, wherein:
the borated succinimide dispersant is obtained by an “ene” reaction of a polyalkylene with an acylating agent to form an intermediate, reacting the intermediate with an aminoalcohol or amine to form a dispersant, and reacting the dispersant with a borating agent to form a borated succinimide dispersant; and
the non-borated succinimide dispersant is obtained/obtainable by a “Diels-Alder” reaction of a polyalkylene with an acylating agent to form an intermediate, and reacting the intermediate with an aminoalcohol or amine to form a non-borated succinimide dispersant.

23. The lubricating composition of claim 21, wherein the borated succinimide dispersant has 0.35 wt % to 0.95 wt % boron on an oil-free basis of the borated succinimide dispersant.

24. The lubricating composition of claim 21, wherein the borating agent comprises boric acid (including metaboric acid, HBO₂, orthoboric acid, H₃BO₃, and tetraboric acid, H₂B₄O₇), boric oxide, boron trioxide, and alkyl borates, such as those of the formula (RO)ₓB(OH)_{y} wherein x is 1 to 3 and y is 0 to 2, the sum of x and y being 3, and where R is an alkyl group containing 1 to 6 carbon atoms.

25. The lubricating composition of claim 21, wherein the dispersant package is present at 2.5 wt % to 3 wt % of the lubricating composition.

26. The lubricating composition of claim 21, wherein the amine comprises an aliphatic polyamine, or mixtures thereof.

27. The lubricating composition of claim 26, wherein the aliphatic polyamine is selected from the group consisting of ethylenediamine, diethylenetriamine, triethylenetetramine, tetraethylenepentamine, pentaethylenehexamine, polyamine still bottoms, and mixtures thereof.

28. The lubricating composition of claim 21, wherein the ratio of non-borated dispersant to borated dispersant is 85:15 to 60:40.
